(19) United States
(12) Patent Application Publication
(10) Pub. No.: US 2025/0102925 A1
(43) Pub. Date: Mar. 27, 2025

(54) PROCESSING APPARATUS AND ARTICLE MANUFACTURING METHOD

(71) Applicant: CANON KABUSHIKI KAISHA, Tokyo (JP)

(72) Inventors: SHIORI OTOMO, Tochigi (JP); HIROSHI MORIKAWA, Tochigi (JP); MASATO ANZAI, Tochigi (JP); YUJI ISHII, Tochigi (JP); TOMOYASU HATA, Tochigi (JP)

(21) Appl. No.: 18/888,572

(22) Filed: Sep. 18, 2024

(30) Foreign Application Priority Data
Sep. 25, 2023 (JP) 2023-161707

(51) Int. Cl. G03F 7/00; G03F 7/20

(52) U.S. Cl. CPC G03F 7/70725; G03F 7/70775; G03F 7/20

(57) ABSTRACT

A processing apparatus performs a predetermined process with respect to a substrate. The apparatus includes a driver configured to drive a stage that holds the substrate, a first controller configured to operate at a first frequency and control the driver, a second controller configured to operate at a second frequency higher than the first frequency and generate a command based on a position of the stage, and a device configured to perform one of the predetermined process in response to the command and a preparation process for the predetermined process.

### BACKGROUND OF THE INVENTION

### Field of the Invention

The present invention relates to a processing apparatus and an article manufacturing method.

### Description of the Related Art

In a substrate stage apparatus, the position of a substrate can be detected based on the position of a stage and the position (relative position in the field of view of a scope (camera)) of a mark on the substrate that is detected using the scope. Recently, to improve the throughput, the position of a substrate can be measured while the stage is moved.

However, when detecting the position of a substrate while moving the stage, the mark needs to be imaged immediately when it enters the field of view of the scope. When a high-power scope is used, the field of view becomes dark. Thus, a high-brightness illumination is necessary to detect the position of a substrate while moving the stage at a higher stage. Flash photographing may be performed using a plurality of light-emitting diodes (LEDs). When flash photographing is performed, misregistration can occur in an image owing to a light emission timing error between a plurality of LED tubes. Japanese Patent Laid-Open No. 2007-10734 discloses a method of correcting the time of a light emission trigger so that the emission timings of a plurality of LEDS coincide with each other.

Also, when detecting the position of a substrate while moving the stage, if the imaging time of the mark is long, the image of the mark stretches. To solve this, Japanese Patent Laid-Open No. 2015-233106 discloses a method of outputting a gate signal of a short time when a mark falls within a detection range, and capturing an instantaneous image of the mark. Further, a mark may deviate from the field of view due to a substrate arrangement error and may not be imaged. To prevent this, Japanese Patent Laid-Open No. 2007-10735 discloses a method of calculating in advance the average value of substrate positional error amounts with respect to a mark measurement unit, and when the positional error amount deviates from the allowance of the positional error amount, adjusting the position of a camera unit.

However, when detecting the position of a substrate while moving the stage, a conventional apparatus can issue an imaging command only in units of the stage control frequency of a stage control board, and an actual imaging command timing shifts from an ideal imaging command timing. Owing to the shift of the imaging command timing, the mark deviates from the field of view of the scope and cannot be imaged. Conventionally, it is difficult to accurately process a substrate when the stage moves.

### SUMMARY OF THE INVENTION

The present invention provides a technique advantageous for accurately processing a substrate even when a stage moves.

A first aspect of the present invention provides a processing apparatus that performs a predetermined process with respect to a substrate, comprising: a driver configured to drive a stage that holds the substrate; a first controller configured to operate at a first frequency and control the driver; a second controller configured to operate at a second frequency higher than the first frequency and generate a command based on a position of the stage; and a device configured to perform one of the predetermined process in response to the command and a preparation process for the predetermined process.

A second aspect of the present invention provides an article manufacturing method comprising: a processing apparatus which is specified as the first aspect and constituted as an exposure apparatus configured to print the pattern to the substrate by projecting the pattern of the master to the substrate; developing the substrate having undergone the exposing; and processing the substrate having undergone the developing, thereby obtaining an article.

A third aspect of the present invention provides an article manufacturing method comprising: transferring a second substrate to a first substrate by a processing apparatus which is specified as the first aspect and constituted to perform the transferring; and processing a structure in which the second substrate is transferred to the first substrate by the transferring, thereby obtaining an article.

Further features of the present invention will become apparent from the following description of exemplary embodiments with reference to the attached drawings.

### BRIEF DESCRIPTION OF THE DRAWINGS

FIG. 1 is a view showing the arrangement of an exposure apparatus according to the first embodiment;

FIG. 2 is a block diagram showing an arrangement associated with position control of a substrate stage in the exposure apparatus according to the first embodiment;

FIG. 3 is a sequence chart exemplifying the sequence of a detection process of detecting the position of a mark in the exposure apparatus according to the first embodiment;

FIG. 4 is a block diagram showing an arrangement associated with position control of a substrate stage in an exposure apparatus according to the second embodiment;

FIG. 5 is a block diagram showing an arrangement associated with position control of a substrate stage in an exposure apparatus according to the third embodiment;

FIG. 6 is a view exemplifying the relationship between the field of view and mark of first and second mark detection systems;

FIG. 7 is a view showing an arrangement example of a laser irradiation system as a processing apparatus according to the fourth embodiment; and

FIG. 8 is a block diagram showing an arrangement associated with position control of a substrate stage in the laser irradiation system according to the fourth embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

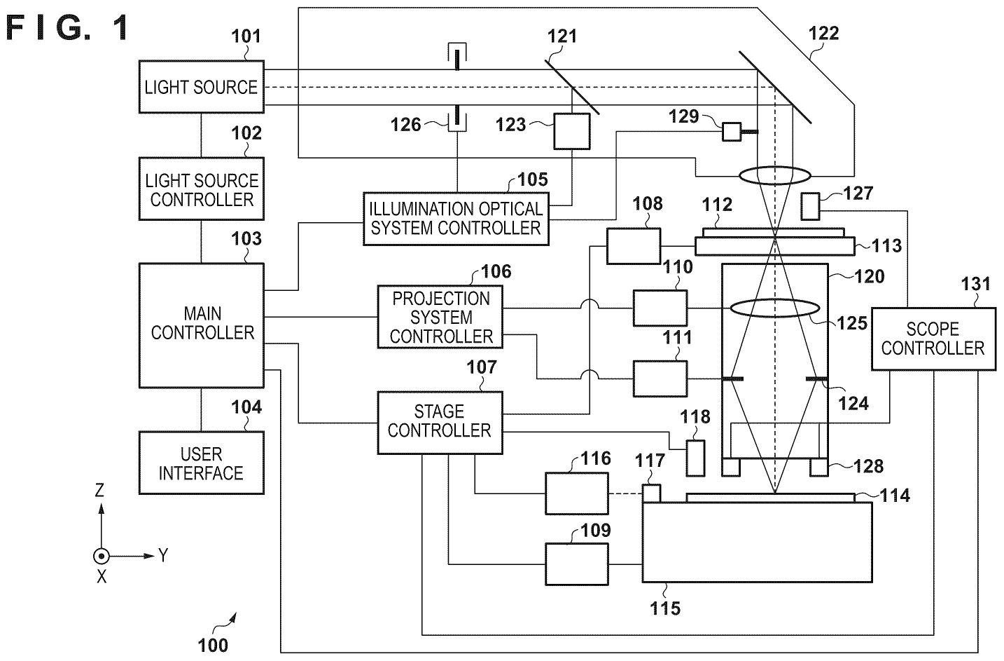

FIG. 1 shows the arrangement of an exposure apparatus 100 according to the first embodiment. The exposure apparatus 100 is an example of a processing apparatus that performs a predetermined process with respect to a substrate. The exposure apparatus 100 performs an exposure process as the predetermined process. The exposure apparatus 100 will be explained here as an example of the processing apparatus. However, the processing apparatus may be constituted as another apparatus such as an apparatus that chemically or mechanically processes a substrate, an apparatus that arranges or supplies a solid or a liquid at a predetermined position on a substrate, or an apparatus that inspects a substrate.

The exposure apparatus 100 can be constituted as, for example, a scanning exposure apparatus, but may be constituted as another type of exposure apparatus. The exposure apparatus 100 can be configured to print the pattern of a master 112 to a substrate 114. More specifically, the exposure apparatus 100 includes a projection optical system 120 that projects the pattern of the master 112 to the substrate 114. A print image corresponding to the pattern of the master 112 is formed on the substrate 114 by the exposure process. The substrate 114 has a photoresist, and the print image can be formed as a latent image on the photoresist. The latent image can be converted into a resist pattern serving as a physical pattern by a development step.

The exposure apparatus 100 can include a user interface 104. A user such as an operator can operate the user interface 104 to input various kinds of information to the exposure apparatus 100.

The arrangement of the exposure apparatus 100 will be explained in more detail. In FIG. 1, X-, Y-, and Z-coordinates are defined such that a direction that is parallel to the optical axis of the projection optical system 120 and is from the substrate 114 toward the master 112 serves as the Z-axis, and directions orthogonal to the Z-axis serve as the Y- and X-axes. A light source 101 emits exposure light. The light source 101 can be controlled by a light source controller 102 controlled by a main controller 103. The exposure light emitted from the light source 101 is shaped into a predetermined beam shape through the shaping optical system (not shown) of an illumination optical system 122. The shaped beam enters an optical integrator (not shown), and the optical integrator forms a plurality of secondary light sources for illuminating the master 112 with a uniform illumination distribution.

The illumination optical system 122 can include an aperture stop 126 that decides the numerical aperture (NA) of the illumination optical system 122. The aperture stop 126 has an almost circular aperture. The numerical aperture (NA) of the illumination optical system 122 is controlled by controlling the diameter of the aperture by an illumination optical system controller 105 controlled by the main controller 103. The ratio of the numerical aperture of the illumination optical system 122 to that of the projection optical system 120 is called a coherence factor (o value). The optical system controller 105 can set the σ value by controlling the aperture stop 126 of the illumination optical system 122.

A half mirror 121 is inserted in the optical path of the illumination optical system 122. Part of exposure light for illuminating the master 112 can be reflected and extracted by the half mirror 121. A photosensor 123 is inserted in the optical path of reflected light of the half mirror 121, and can detect the intensity (exposure energy) of exposure light. The illumination optical system 122 can include a shutter unit 129 for controlling irradiation of the substrate 114 with exposure light. The shutter unit 129 can be controlled by the optical system controller 105 controlled by the main controller 103.

The master 112 can be held by a master stage 113. The master 112 can be driven in the Y-axis direction (scanning direction) by, for example, driving the master stage 113 in the Y-axis direction by a driver 108. The pattern of a device to be manufactured is formed on the master 112. The illumination optical system 122 illuminates the pattern of the master 112 with exposure light. The projection optical system 120 reduces the image of the pattern of the master 112 at a reduction magnification B, and projects the reduced image to the substrate 114. Accordingly, the photoresist of the substrate is exposed, forming the print image of the pattern of the master 112 on the photoresist.

An aperture stop 124 having an almost circular aperture is arranged on the pupil plane (Fourier transform plane with respect to the object plane serving as a plane on which the master 112 is arranged) of the projection optical system 120. The diameter of the aperture of the aperture stop 124 can be controlled by a driver 111 such as a motor. The projection optical system 120 includes one or more optical elements 125. The optical characteristics of the projection optical system 120 can be adjusted by driving one or more optical elements 125 by a driver 110. The drivers 110 and 111 can be controlled by a projection system controller 106 controlled by the main controller 103.

The substrate 114 is held by a substrate stage 115. The substrate stage 115 can be driven by a driver 109 in regard to the X-axis, Y-axis, Z-axis directions and rotations around these axes. The driver 109 that drives the substrate stage 115, and the driver 108 that drives the master stage 113 are controlled by a stage controller 107 controlled by the main controller 103. When the exposure apparatus 100 is constituted as a scanning exposure apparatus, the stage controller 107 controls the drivers 108 and 109 so as to synchronously scan the substrate stage 115 and the master stage 113. A moving mirror or a scale can be provided as a measurement target 117 on the substrate stage 115. Positions of the substrate stage 115 in the X-axis, Y-axis, and Z-axis directions and rotation angles around these axes can be detected by detecting displacements of the measurement target 117 in the X-axis, Y-axis, and Z-axis directions by a laser interferometer or an encoder serving as a measurement instrument 116. The stage controller 107 can feedback-control the position and rotation angle of the substrate stage 115 based on the results of detection by the measurement instrument 116.

The exposure apparatus 100 can include a focus detection system 118. The focus detection system 118 can include a light projecting system through which a plurality of light fluxes having wavelengths to which the photoresist of the substrate 114 is not photosensitive obliquely enter the substrate 114, and a light receiving system that detects light reflected by the substrate 114. The light receiving system has a light receiving element that receives a plurality of light fluxes. A position of the substrate 114 in the Z-axis direction can be detected by detecting the light receiving positions of the respective light fluxes.

The exposure apparatus 100 can include a first mark detection system 127 and/or a second mark detection system 128. The first mark detection system 127 can include one or more first scopes that detect a relative position between the mark of the master 112 and that of the substrate 114 via the projection optical system 120. A relative position between the mark of the master 112 and that of the substrate 114 can be detected using each first scope of the first mark detection system 127. The first mark detection system 127 can include a driving system that drives each first scope along the X-Y plane. The second mark detection system 128 is arranged between the projection optical system 120 and the substrate stage 115, and can include one or more second scopes that detect the position of the mark of the substrate 114. The second mark detection system 128 can include a driving system that drives each second scope along the X-Y plane. The exposure apparatus 100 can simultaneously detect the positions of a plurality of marks using the first and second scopes. Based on results detected using the first and second scopes, the main controller 103 can detect the positional error and shape error between the substrate 114 and the master 112, the distortion of the substrate 114, and the like. Also, the main controller 103 can control an exposure process while adjusting the speeds and positions of the master stage 113 and substrate stage 115, the projection magnification of the projection optical system 120, and the like based on the positional error and shape error between the substrate 114 and the master 112, the distortion of the substrate 114, and the like.

One or more first scopes of the first mark detection system 127, and one or more second scopes of the second mark detection system 128 can be understood as optical devices for performing a preparation process (mark detection process) for a predetermined process (exposure process) with respect to the substrate 114. Alternatively, the predetermined process with respect to the substrate 114 may be regarded as a detection process with respect to the mark of the substrate 114. In this case, one or more first scopes of the first mark detection system 127, and one or more second scopes of the second mark detection system 128 can be understood as optical devices for performing a predetermined process (mark detection process) with respect to the substrate 114. Alternatively, the illumination optical system 122 or the shutter unit 129 (or the optical system controller 105 that controls the shutter unit 129) can be understood as a device for performing a predetermined process (exposure process) with respect to the substrate 114. More specifically, the illumination optical system 122 or the shutter unit 129 can be understood as a device for controlling the (timing of) start and (timing of) end of exposure of the substrate 114. A second controller 136 can be configured to transmit, to the optical system controller 105 based on the position of the substrate stage 115, commands to start and end exposure.

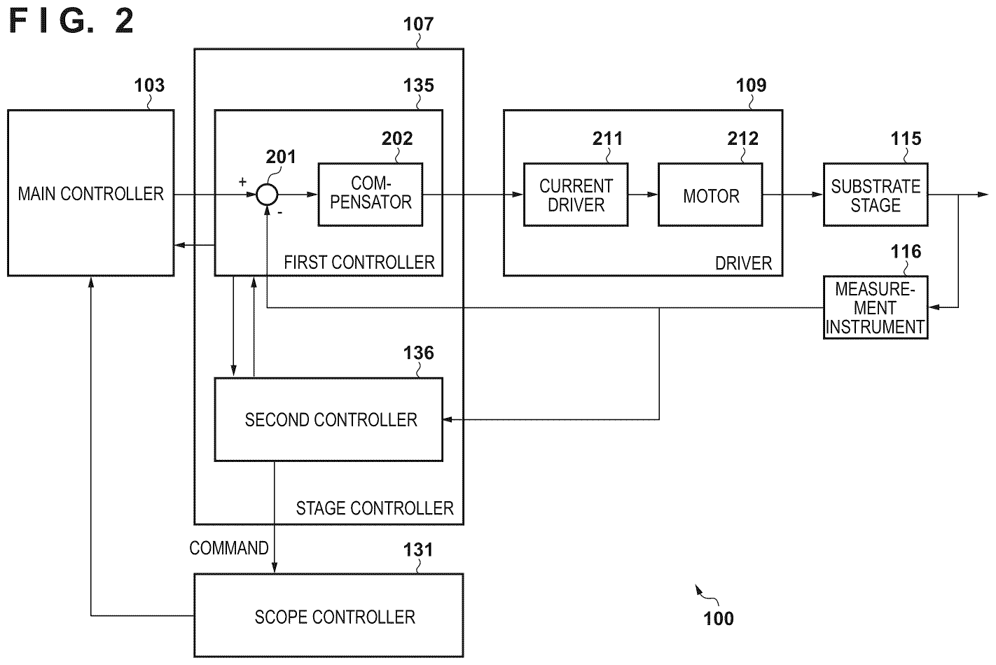

FIG. 2 shows an arrangement associated with position control of the substrate stage 115 in the exposure apparatus 100. Although not shown in FIG. 2, the exposure apparatus 100 can have a similar arrangement associated with position control of the master stage 113. More specifically, the stage controller 107 controlled by the main controller 103 can control the master stage 113 by controlling the driver 108. This arrangement can be an arrangement in which the driver 109, the substrate stage 115, and the measurement instrument 116 in FIG. 2 are replaced with the driver 108, the master stage 113, and a measurement instrument (not shown; a measurement instrument that measures the position of the master stage 113).

As described above, the exposure apparatus 100 serving as a processing apparatus can include the substrate stage 115 that holds a substrate, the driver 109 that drives the substrate stage 115, the stage controller 107 that controls the driver 109, and the measurement instrument 116. The exposure apparatus 100 can also include a scope controller 131 that controls the first mark detection system 127 and the second mark detection system 128 as optical devices for performing a predetermined process with respect to the substrate 114 or a preparation process for the predetermined process. The scope controller 131 can also be understood as a device for performing a preparation process (mark detection process) for a predetermined process (exposure process) with respect to the substrate 114. The exposure apparatus 100 can also include the main controller 103 that controls the stage controller 107. The main controller 103 can control the light source controller 102, the optical system controller 105, the projection system controller 106, the scope controller 131, the user interface 104, and the like, in addition to the stage controller 107.

The stage controller 107 can include a first controller 135 and the second controller 136. The first controller 135 operates at the first frequency and controls the driver 109. The fact that the first controller 135 operates at the first frequency means that the frequency of a clock for operating the first controller 135 is the first frequency. The second controller 136 operates at the second frequency higher than the first frequency, and generates a command based on the position of the substrate stage 115. The fact that the second controller 136 operates at the second frequency means that the frequency of a clock for operating the second controller 136 is the second frequency. The scope controller 131 is an example of a device for performing a preparation process in response to a command generated by the second controller 136.

The main controller 103 inputs a position target value to the first controller 135. Based on the difference (control deviation) between a position target value input from the main controller 103 and position information of the substrate stage 115 input from the measurement instrument 116, the first controller 135 can generate a command value (for example, a current command value) to be input to the driver 109. The first controller 135 can include, for example, a subtracter 201 and a compensator (for example, a PID compensator) 202. The subtracter 201 calculates the difference (control deviation) between a position target value input from the main controller 103 and position information of the substrate stage 115 input from the measurement instrument 116. The compensator 202 generates a command value to the driver 109 based on an output from the subtracter 201. The first controller 135 can receive an output (position information) from the measurement instrument 116 at the first frequency, and generate a command value to the driver 109 at the first frequency. From another viewpoint, the first controller 135 can receive an output (position command value) from the main controller 103 and an output (position information) from the measurement instrument 116 at the first frequency, and generate a command value to the driver 109 at the first frequency in accordance with these outputs. The first frequency can be decided in accordance with the control band of the substrate stage 115. If the first frequency is excessively high, the above-described operation cannot be completed within each cycle of the first frequency, and the substrate stage 115 cannot be properly controlled.

The main controller 103 can be configured to send a mark detection position to the second controller 136 via the first controller 135. Alternatively, the main controller 103 can be configured to send a mark detection position directly to the second controller 136. The mark detection position is the position of the substrate stage 115 at a timing when the mark needs to be detected by (the first scope of) the first mark detection system 127 and/or (the second scope of) the second mark detection system 128. The timing when the mark needs to be detected may be a timing in a period in which the substrate stage 115 (substrate 114) is accelerated, or a timing in a period in which the substrate stage 115 (substrate 114) is driven at an equal speed.

The second controller 136 operates at the second frequency higher than the first frequency at which the first controller 135 operates. The second controller 136 receives an output (position information of the substrate stage 115) from the measurement instrument 116 at the second frequency, and generates a detection command to the scope controller 131 based on the output. That is, since the second controller 136 operating at the second frequency generates a detection command, the detection command can be generated at a higher time resolution than by an arrangement in which the first controller 135 operating at the first frequency generates a measurement command. The (value of) second frequency can be decided so that (the first scope of) the first mark detection system 127 and/or (the second scope of) the second mark detection system 128 can perform imaging based on the detection command.

In response to the detection command, the scope controller 131 controls (the first scope of) the first mark detection system 127 and/or (the second scope of) the second mark detection system 128 to perform a mark detection process (preparation process). Since the detection command generated at a high time resolution is input to the scope controller 131, the scope controller 131 can control the first mark detection system 127 and/or (the second scope of) the second mark detection system 128 to perform imaging at an accurate timing. That is, (the first scope of) the first mark detection system 127 and/or (the second scope of) the second mark detection system 128 can image a mark at a timing when the mark falls within the field of view.

The scope controller 131 can be configured to detect the position of the mark imaged by (the first scope of) the first mark detection system 127 and/or (the second scope of) the second mark detection system 128, and send the detection result to the main controller 103. The main controller 103 generates a position command value so as to drive the substrate 114 to a target position based on the output (mark position information) from the scope controller 131, and sends the position command value to the first controller 135. Accordingly, the master 112 having a pattern to be printed on the substrate 114, and the substrate 114 are aligned.

The second controller 136 can be configured to send, to the scope controller 131, detection parameter values such as brightness, magnification, and accumulation time, in addition to a detection command. These detection parameter values may be sent to the scope controller 131 together with a detection command, or to the scope controller 131 at a timing different from that of a detection command. Measurement parameter values can be decided in accordance with the driving conditions of the substrate stage 115. For example, when the driving speed of the substrate stage 115 changes before detecting the next mark after detecting a given mark, the brightness and the accumulation time need to be changed to those suited to a driving speed of the substrate stage 115 at the time of detecting the next mark. This can reduce a mark position detection error.

The main controller 103 may correct a mark position output from the scope controller 131 by using the position target value (mark detection position) of the substrate stage 115 at a timing when the position of a mark is detected, and position information of the substrate stage 115 at the time of a detection command. The corrected mark position P can be given by equation (1):

$$P = Pm + ( Ps - Pt ) \qquad ( 1 )$$

where Pm is a mark position output from the scope controller 131, Pt is a mark detection position, and Ps is a position of the substrate stage 115 at a timing when a detection command is generated.

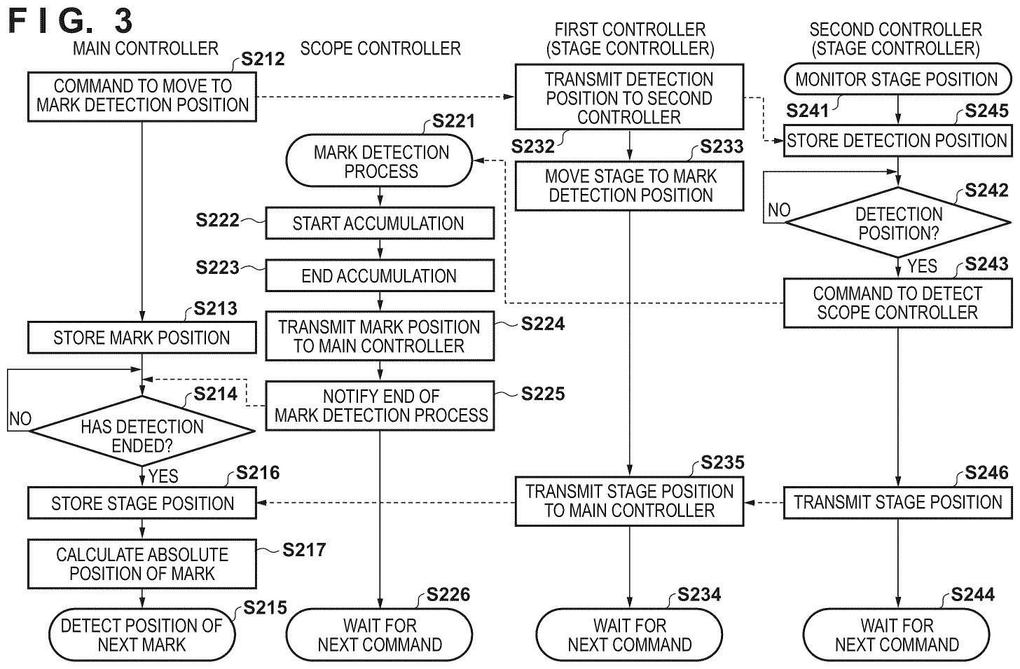

FIG. 3 exemplifies the sequence of a detection process of detecting the position of a mark. An example of the detection process will be explained with reference to FIG. 3. In step S212, the main controller 103 transmits a movement command to the first controller 135 to move the substrate stage 115 to the mark detection position (Pt). In step S232, the first controller 135 transmits a mark detection position to the second controller 136. In step S233, the first controller 135 moves the substrate stage 115 to the mark detection position.

In step S241, the second controller 136 monitors the position of the substrate stage 115 based on an output from the measurement instrument 116. In step S245, the second controller 136 stores the mark detection position that has been received from the first controller 135 in step S232. In step S242, the second controller 136 waits until the position of the substrate stage 115 reaches the mark detection position. After the position of the substrate stage 115 reaches the mark detection position, the second controller 136 transmits an accumulation start signal to the scope controller 131 in step S243. Also, the second controller 136 transmits a detection parameter value to the scope controller 131. Note that the detection parameter value transmitted to the scope controller 131 can be optimized in accordance with the driving state of the substrate stage 115.

In step S221, the scope controller 131 starts a mark detection process in response to reception of the accumulation start signal that has been transmitted from the second controller 136 in step S243. In step S222, the scope controller 131 starts an accumulation process (imaging) of an electric signal (charge) corresponding to the optical image of the mark in accordance with the detection parameter value. In step S223, the scope controller 131 ends the accumulation process (imaging) in accordance with the detection parameter value. In step S224, the scope controller 131 calculates the mark position (Pm) based on the obtained mark image, and transmits mark position information (calculation result) to the main controller 103.

In step S213, the main controller 103 stores the mark position information received from the scope controller 131. In step S225, the scope controller 131 notifies the main controller 103 of the end of the mark detection process. In step S226, the scope controller 131 waits for the next detection command (step S243) from the second controller 136.

In step S214, the main controller 103 waits for a mark detection process end notification (step S225) from the scope controller 131, and upon receiving the mark detection process end notification, ends the mark detection process. In step S246, the second controller 136 transmits, to the first controller 135, the position (Ps) of the substrate stage 115 at the time of transmitting a detection command. In step S244, the second controller 136 waits for a command from the first controller 135 to move to the next mark detection position (step S232).

In step S235, the first controller 135 transmits position information of the substrate stage 115 to the main controller 103. In step S234, the first controller 135 waits for a command transmitted from the main controller 103 for driving to the next mark detection position (step S212).

In step S216, the main controller 103 stores the position information of the substrate stage 115 received from the first controller 135. In step S217, the main controller 103 calculates a corrected mark position based on the mark position (Pm) output from the scope controller 131, the mark detection position (Pt), and the position (Ps) of the substrate stage 115 at the time of transmitting a detection command. Also, the main controller 103 can decide the absolute position of the mark based on the corrected mark position (that is, mark position (relative position) within the field of view of the scope), and the position of the substrate stage 115 at the time of detecting a mark position. In step S215, the main controller 103 shifts to detection of the position of the next mark (step S212). The above-described process is repetitively performed, detecting the positions of a plurality of marks to be detected.

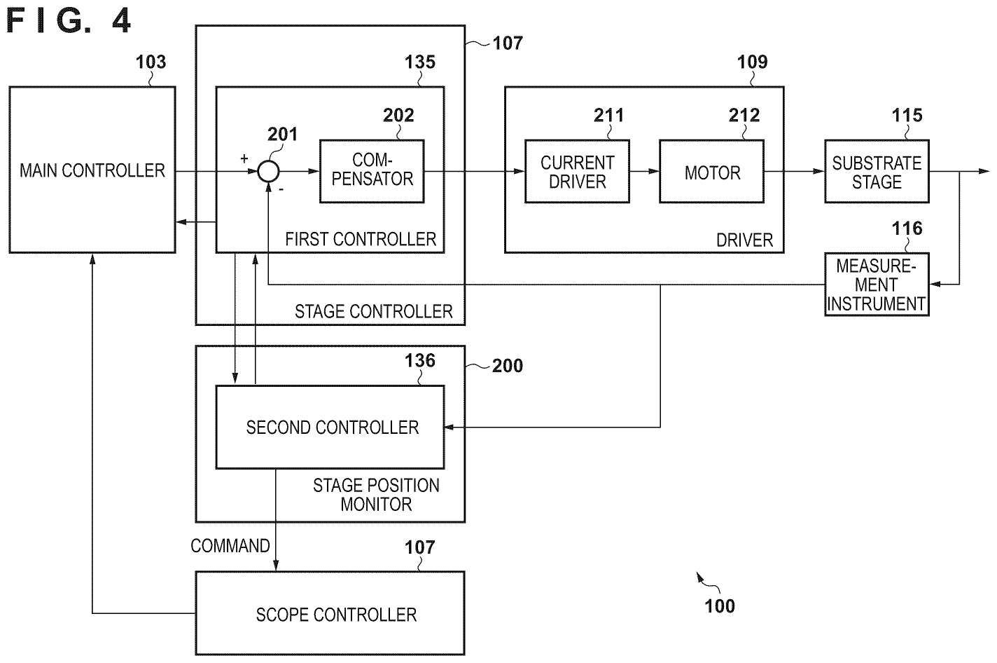

FIG. 4 shows an arrangement associated with position control of a substrate stage 115 in an exposure apparatus 100 according to the second embodiment. Matters which will not be mentioned in the second embodiment can be pursuant to the first embodiment. In the second embodiment, a stage position monitor 200 is provided to monitor the position of the substrate stage 115, and a second controller 136 is incorporated in the stage position monitor 200. A measurement instrument 116 includes, for example, an encoder that outputs a pulse signal at the time of driving the substrate stage 115. The second controller 136 counts pulse signals to measure the position of the substrate stage 115. The stage position monitor 200 (second controller 136) can be configured to operate at a frequency equal to or higher than the frequency of the pulse signal output from the encoder. Hence, the position of the substrate stage 115 can be monitored at a minimum time resolution capable of measurement by the encoder, and a mark can be imaged in a state in which the mark falls within the field of view of a detection system (scope).

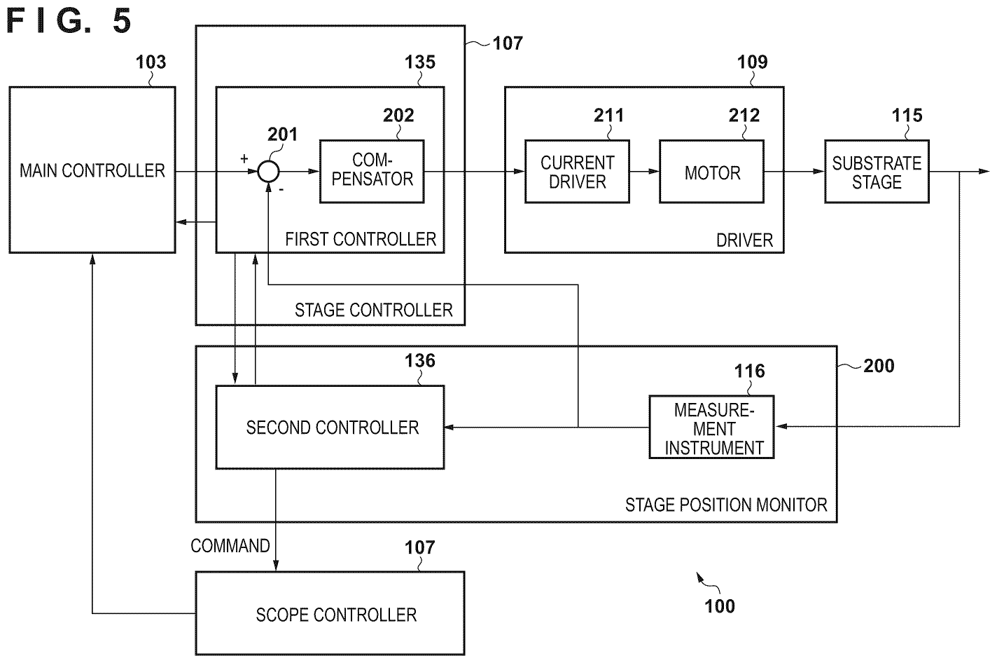

FIG. 5 shows an arrangement associated with position control of a substrate stage in an exposure apparatus 100 according to the third embodiment. Matters which will not be mentioned in the third embodiment can be pursuant to the first or second embodiment. In the third embodiment, a stage position monitor 200 is provided to monitor the position of a substrate stage 115, and a second controller 136 and a measurement instrument 116 are incorporated in the stage position monitor 200.

In the first to third embodiments, a first controller 135 can be configured to receive, from a main controller 103, a detection parameter set for detecting a mark position, and set the detection parameter set in the second controller 136. The detection parameter set can include information representing the above-mentioned mark detection position. The second controller 136 can be configured to obtain the position of a substrate 114 from the measurement instrument 116 that measures the position of the substrate stage 115, and output a detection command to a scope controller 131 in accordance with the detection parameter set that is set from the first controller 135.

The first controller 135 can be configured to receive a driving parameter set from the main controller 103, and output a command value to a driver 109 in accordance with the driving parameter set. The driving parameter set can include, for example, the position, speed, and acceleration of the substrate stage 115. The first controller 135 can feedback-control the substrate stage 115 based on the position target value of the substrate stage 115, and the current position of the substrate stage 115 that is measured by the measurement instrument 116. The current position of the substrate stage 115 that is measured by the measurement instrument 116 may be directly provided to the first controller 135 via the second controller 136 or directly provided from the measurement instrument 116 to the first controller 135.

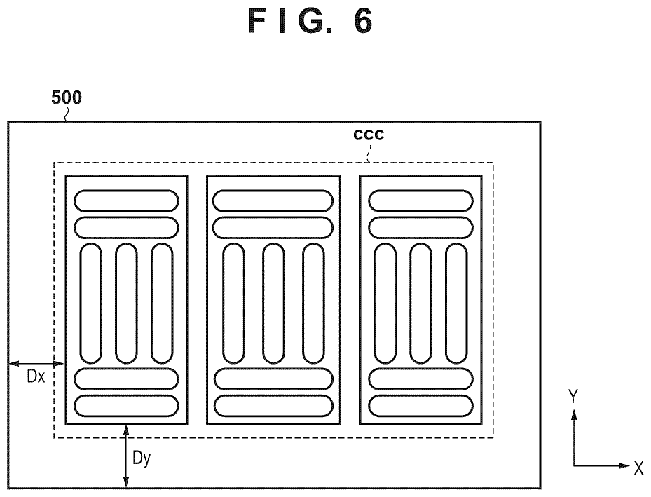

A method of deciding the frequency of a clock, that is, the second frequency at which the second controller 136 is operated will be explained. FIG. 6 exemplifies the relationship between a mark ccc and a field 500 of view of the scope of each of a first mark detection system 127 and second mark detection system 128. Dx represents an allowable positional error amount when the substrate stage 115 is driven in the X-axis direction. Dy represents an allowable positional error amount when the substrate stage 115 is driven in the Y-axis direction. That is, Dx and Dy represent mark measurement positional error amounts allowed to accurately detect the position of a mark while the substrate stage 115 is driven in the X-axis direction or the Y-axis direction. Note that Dx and Dy represent distances from the end of the mark ccc to that of the field 500 of view when the mark ccc is arranged at the center of the field 500 of view.

When the position of a mark is detected while the substrate stage 115 is moved, the allowable positional error amounts Dx and Dy change depending on the driving speed of the substrate stage 115. That is, if the driving speed of the substrate stage 115 is low, the position of the mark can be accurately detected even when the operating frequency (second frequency) of the second controller 136 is set to be low. In contrast, if the driving speed of the substrate stage 115 is high, it is necessary to set a high operating frequency (second frequency) of the second controller 136. In deciding the allowable positional error amounts Dx and Dy, the movement amount of the mark within the field 500 of view during the accumulation period needs to be considered.

From this, to accurately detect the position of a mark while moving the substrate stage 115, a second frequency f serving as the operating frequency of the second controller 136 can be decided as follows.

First, a mark positional error amount that can take both Dx and Dy is defined as D, a mark arrangement error is defined as Ep, a substrate arrangement error is defined as Es, a mark movement amount in the imaging period (accumulation period) is defined as Ds, and the driving speed of the substrate stage 115 is defined as v.

Then, letting v be the driving speed of the substrate stage 115, a position measurement cycle T of the substrate stage 115 desirably satisfies conditions given by the following relations:

$$v \times T < D - ( Ds + Ep + Es ) \qquad ( 2 )$$

$$f > \frac{v}{D - ( Ds + Ep + Es )} \qquad ( 3 )$$

Therefore, the position measurement frequency f desirably satisfies a condition given by the following relation. That is, the second frequency f serving as the operating frequency of the second controller 136 is desirably decided in accordance with the relation (4):

$$f > \frac{v}{D - ( Ds + Ep + Es )} \qquad ( 4 )$$

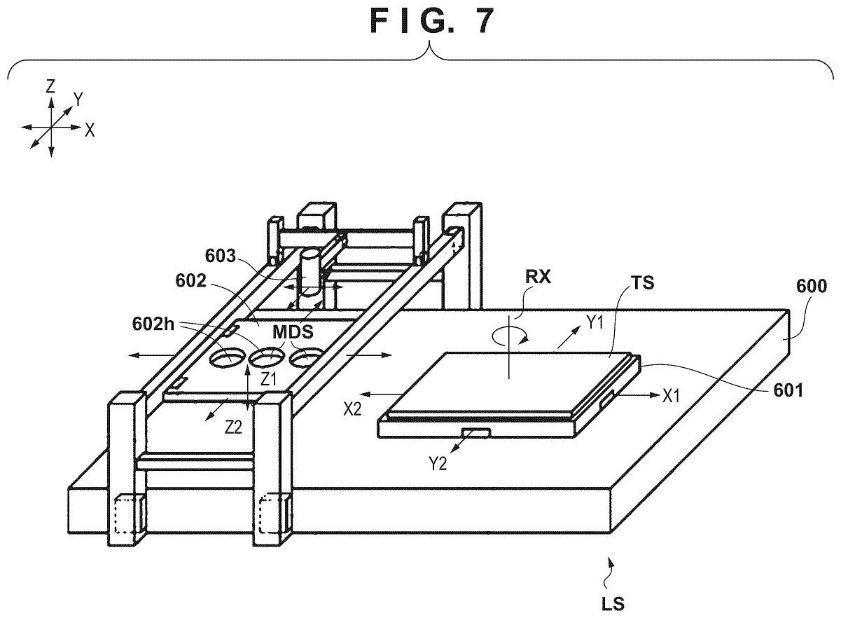

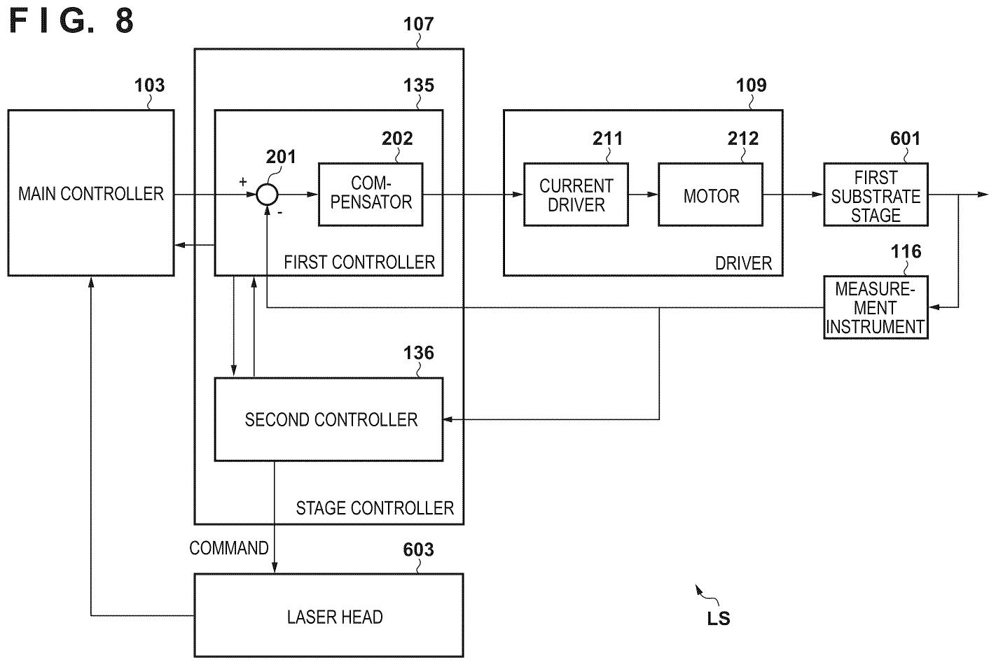

FIG. 7 shows an arrangement example of a laser irradiation system LS as a processing apparatus according to the fourth embodiment. FIG. 8 shows an arrangement example of a control system incorporated in the laser irradiation system LS. In the fourth embodiment, the laser irradiation system LS is constituted as a mass transfer apparatus. The laser irradiation system LS can include a stage base 600, a first substrate stage 601, a second substrate stage 602, and a laser head 603. The first substrate stage 601 can hold a target substrate (first substrate) TS, and be driven by a first driver (not shown). The second substrate stage 602 has a plurality of openings 602h, and can be configured to hold a microdevice substrate (second substrate) MDS in each opening 602h.

Each microdevice substrate MDS can have a plurality of microdevices. The second substrate stage 602 can be driven by a second driver (not shown). A laser beam emitted from the laser head 603 irradiates a microdevice (not shown) to be transferred, and then the microdevice to be transferred can be separated from a microdevice substrate SB and transferred to the target substrate TS. That is, the laser irradiation system LS (mass transfer apparatus) in this arrangement example employs a laser liftoff (LLO) technique to transfer a microdevice. The laser irradiation system LS can be understood as a processing apparatus that performs a predetermined process with respect to the target substrate (first substrate) TS, more specifically, a transfer process with respect to the target substrate (first substrate) TS to transfer a microdevice. The laser head 603 can be understood as a device that performs the predetermined process (transfer process).

The first substrate stage 601 is arranged on the stage base 600. The first substrate stage 601 holds the target substrate TS, and is driven by a driver 109 so as to move and rotate on the stage base 600. The first substrate stage 601 is configured to be two-dimensionally movable along, for example, movement axes X and Y, and can move in, for example, a direction X1 (or a direction X2) and a direction Y1 (or a direction Y2). The axis direction of the movement axis X (for example, the direction X1 or X2) crosses that of the movement axis Y (for example, the direction Y1 or Y2).

The second substrate stage 602 is arranged apart from the stage base 600, and configured to hold the microdevice substrate MDS and be movable and rotatable relatively to the first substrate stage 601. In the fourth embodiment, the second substrate stage 602 can three-dimensionally move along the movement axes X, Y, and Z in order to move in, for example, the direction X1 (or the direction X2), the direction Y1 (or the direction Y2), and a direction Z1 (or a direction Z2).

The laser head 603 is arranged apart from the first substrate stage 601, and can emit a laser beam to a microdevice to be transferred on the microdevice substrate MDS held by the second substrate stage 602. In the example of FIG. 7, the laser head 603 is configured to be movable in the direction X1 (or the direction X2) and the direction Y1 (or the direction Y2).

After the target substrate TS is held by the first substrate stage 601 and a plurality of microdevice substrates MDS are held by the second substrate stage 602, a microdevice transfer sequence can start. A main controller 103 can control the first substrate stage 601, the second substrate stage 602, and the laser head 603 in accordance with preset process parameters. Recently, the mass transfer apparatus serving as the laser irradiation system LS needs to shorten the manufacturing process time. As one of measures, for example, it is considered to transfer microdevices to the target substrate TS at a predetermined interval while driving the first substrate stage 601.

A case where microdevices are transferred to the target substrate TS while driving the first substrate stage 601 in a predetermined direction in the microdevice transfer sequence will be exemplified below. A first controller 135 can control the driver 109 so as to drive the first substrate stage 601 in a predetermined direction. A second controller 136 can monitor the position of the first substrate stage 601 based on an output from a measurement instrument 116. The second controller 136 operates at a frequency higher than that of the first controller 135 that controls the first substrate stage 601. Hence, the second controller 136 can monitor the position of the first substrate stage 601 at a time resolution higher (time interval finer) than that of the first controller 135 that controls the first substrate stage 601.

The second controller 136 can be configured to transmit an irradiation command to the laser head 603 when the first substrate stage 601 reaches a preset position. The laser head 603 can be configured to irradiate the microdevice substrate MDS with a laser beam in response to the irradiation command, and transfer a microdevice to be transferred to the target substrate TS.

The adoption of the second controller 136 operating at the second frequency higher than the first frequency at which the first substrate stage 601 is controlled is advantageous for accurately transferring a microdevice to a predetermined position even while driving the first substrate stage 601. Even in the transfer sequence in which the first substrate stage 601 can move irregularly, the second controller 136 operates independently of the first controller 135, and a microdevice can be accurately transferred to a predetermined position.

As another embodiment, an article manufacturing method of manufacturing an article using the processing apparatus according to the above-described embodiment will be explained. The article manufacturing method can include the first process step of performing a predetermined process as the first process with respect to a substrate using the processing apparatus, and the second process step of performing the second process with respect to the substrate having undergone the first process step.

When the processing apparatus is constituted as an exposure apparatus, the predetermined process can be an exposure process. In this case, the article manufacturing method can include an exposure step of exposing a substrate by the exposure apparatus serving as the processing apparatus, and a development step of developing the substrate having undergone the exposure step. The article manufacturing method can further include a process step of processing the substrate having undergone the development step, thereby obtaining an article. The process step can include, for example, an oxidation step, an ion implantation step, or an etching step.

When the processing apparatus is constituted as a laser irradiation system (mass transfer apparatus), the predetermined process can be a transfer process. In this case, the article manufacturing method can include a transfer step of transferring the second substrate to the first substrate by the laser irradiation system serving as the processing apparatus, and a process step of processing a structure in which the second substrate is transferred to the first substrate by the transfer step, thereby obtaining an article.

### OTHER EMBODIMENTS

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-161707, filed Sep. 25, 2023, which is hereby incorporated by reference herein in its entirety.

What is claimed is:

1. A processing apparatus that performs a predetermined process with respect to a substrate, comprising:
a driver configured to drive a stage that holds the substrate;
a first controller configured to operate at a first frequency and control the driver;
a second controller configured to operate at a second frequency higher than the first frequency and generate a command based on a position of the stage; and
a device configured to perform one of the predetermined process in response to the command and a preparation process for the predetermined process.

2. The apparatus according to claim 1, further comprising a measurement instrument configured to measure the position of the stage,
wherein the second controller sends the command to the device based on an output from the measurement instrument.

3. The apparatus according to claim 2, wherein the measurement instrument includes one of an interferometer and an encoder.

4. The apparatus according to claim 2, wherein the first controller receives an output from the measurement instrument at the first frequency, and generates a command value to the driver at the first frequency.

5. The apparatus according to claim 1, wherein the device includes a controller configured to control an optical device for performing the preparation process.

6. The apparatus according to claim 5, wherein the optical device includes a controller configured to control a scope for detecting a position of a mark of the substrate.

7. The apparatus according to claim 6, wherein the second frequency is decided to be able to image the mark by the scope based on the command.

8. The apparatus according to claim 6, further comprising a main controller configured to control the first controller to position the substrate based on an output from the device.

9. The apparatus according to claim 6, further comprising a main controller configured to control the first controller to align a master having a pattern to be printed to the substrate, and the substrate based on an output from the device.

10. The apparatus according to claim 9, wherein the predetermined process includes a process of printing the pattern to the substrate.

11. The apparatus according to claim 9, wherein the processing apparatus is constituted as an exposure apparatus configured to print the pattern to the substrate by projecting the pattern of the master to the substrate.

12. The apparatus according to claim 1, wherein the predetermined process includes a process of transferring a second substrate to a first substrate serving as the substrate, and
the device includes a laser head configured to transfer the second substrate to the first substrate in response to the command.

13. An article manufacturing method comprising:
exposing a substrate by a processing apparatus defined in claim 11;
developing the substrate having undergone the exposing; and
processing the substrate having undergone the developing, thereby obtaining an article.

14. An article manufacturing method comprising:
transferring a second substrate to a first substrate by a processing apparatus defined in claim 12; and
processing a structure in which the second substrate is transferred to the first substrate by the transferring, thereby obtaining an article.
